(19) United States
(12) Patent Application Publication
(10) Pub. No.: US 2026/0329166 A1
(43) Pub. Date: Oct. 22, 2026

(54) PELLICLE AND METHODS FOR FORMING PELLICLE FOR USE IN A LITHOGRAPHIC APPARATUS

(71) Applicants: ASML NETHERLANDS B.V., Veldhoven (NL); IMEC v.z.w., Leuven (BE)

(72) Inventors: Paul Alexander VERMEULEN, Best (NL); Emily Elizabeth GALLAGHER, Burlington, VT (US); Ivan Karel Arthur POLLENTIER, Langdorp (BE); Steven BREMS, Leuven (BE)

(73) Assignees: ASML NETHERLANDS B.V., Veldhoven (NL); IMEC v.z.w., Leuven (BE)

(21) Appl. No.: 19/105,680

(22) PCT Filed: Sep. 8, 2023
(86) PCT No.: PCT/EP2023/074764

§ 371 Date: Feb. 21, 2025

Related U.S. Application Data
(60) Provisional application No. 63/451,809, filed on Mar. 13, 2023.

(30) Foreign Application Priority Data
Sep. 12, 2022 (EP) 22195223.7

(51) Int. Cl. G03F 1/64; G03F 7/00

(52) U.S. Cl. CPC G03F 1/64; G03F 7/70983

(57) ABSTRACT

A pellicle for use in a lithographic apparatus, the pellicle includes: a membrane, the membrane having a first portion and a second portion; and a protective portion at the second portion on at least one side of the membrane. A method for forming a pellicle for use in a lithographic apparatus, the method including: providing a membrane having a first portion and a second portion, and providing a protective portion at the second portion on at least one side of the membrane.

### CROSS-REFERENCE TO RELATED APPLICATIONS

This application claims priority of EP application 22195223.7 which was filed on 12 Sep. 2022 and U.S. application 63/451,809 which was filed on 13 Mar. 2023 and which are incorporated herein in its entirety by reference.

### FIELD

The present description relates to a pellicle for use in a lithographic apparatus and associated methods for forming such a pellicle. The present description also relates to a lithographic apparatus comprising a pellicle disposed in a path of a radiation beam of the lithographic apparatus (used for forming an image on a substrate).

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

A patterning device (e.g., a mask) is used to impart a pattern to a radiation beam in a lithographic apparatus. The patterning device may be protected by a pellicle from particle contamination. The pellicle may be supported by a pellicle frame.

A typical pellicle is a membrane which is located away from the patterning device and is out of the focal plane of a lithographic apparatus in use. Because the pellicle is out of the focal plane of the lithographic apparatus, contamination particles which land on the pellicle are out of focus in the lithographic apparatus. Consequently, images of the contamination particles are not projected onto the substrate. If the pellicle were not present, then a contamination particle which landed on the patterning device may be projected onto the substrate and may introduce a defect into the projected pattern.

It may be desirable to provide an apparatus and/or method that obviates or mitigates one or more problems associated with the prior art.

### SUMMARY

According to a first aspect, there is provided a pellicle for use in a lithographic apparatus, the pellicle comprising: a membrane, the membrane comprising a first portion and a second portion; and a protective portion at the second portion on at least one side of the membrane. For example, the pellicle for use in a lithographic apparatus is a pellicle comprising: a membrane comprising carbon nanotubes, the membrane comprising a first portion and a second portion; and a protective portion at the second portion on at least one side of the membrane, wherein the protective portion comprises a material that is suitable to protect the second portion of the membrane from etching.

The membrane may for example comprise a layer having the same type of carbon nanotubes in both the first portion and the second portion, and wherein the material of the protective portion covering the second portion of the membrane is transparent to at least a fraction of the EUV imaging radiation received by the first portion.

An advantage is that the lifetime of the pellicle may be increased without affecting the performance of the lithographic apparatus.

The protective portion may be only at or on the second portion. The protective portion may be not at or on the first portion. The protective portion may be at or on the first portion to a lesser extent than at or on the second portion. The protective portion may be directly on, in contact with and/or supported by the membrane. The protective portion may be for example a layer which is thick enough to chemically protect the second portion from an (e.g. plasma) etching environment, while it is still thin enough such that the second portion remains substantially transmissive to EUV radiation. The protective portion may be a layer of material deposited in direct contact with the membrane, or it may be thicker because it was etched away to a lesser extent than the first portion in the membrane manufacturing process. In other words, if the first and second portions is the same, then the difference between the first and second portions is that the second portion is thicker than the first portion of the membrane. The material of the protective portion could alternatively be different than the material of the second portion of the membrane and/or of the entire membrane. The material of the protective portion is generally referred below as a “capping material”. For example, if the membrane core is made from carbon nanotubes of certain characteristics (dimensional, etc), the capping material forming the protective portion can comprise either a different material, or carbon nanotubes with different characteristics than the membrane. However it may also have the same carbon nanotube composition as the membrane (core), as long as the second portion is thicker than the first portion (wherein the protective portion is the layer of carbon nanotubes with a thickness equal to the difference in thickness between the first and second portions).

Alternatively, the protective portion may be a freestanding element separated from the membrane (e.g. by a gap). The freestanding element may be for example a plate, a stiff membrane or a protrusion-like element. In this case, the protective portion may still be considered to be adjacent to/on at least one side of the membrane.

The at least one side of the membrane may be a front side of the membrane. That is, the side that the EUV radiation (EUV radiation beam B) is incident on from the radiation source SO and/or illumination system. The front side may be opposite a back side (second side), i.e. the side facing a patterning device in use. The front side may be opposite the side attached to a pellicle frame.

The second portion, in use, may not receive EUV imaging radiation or may receive only a fraction of the EUV imaging radiation received by the first portion. However, for clarity, the second portion is transmissive to EUV imaging radiation such that in case that the second portion, in use, would receive EUV imaging radiation or a fraction of the EUV imaging radiation received by the first portion, then at least part of the received EUV radiation is transmitted through the membrane.

The second portion may be an unexposed region, e.g. that etches more quickly during exposure. This higher etching rate of a second, unexposed region may be due to being at a lower temperature than the exposed region, in a regime where carbon-based films have a higher etch rate.

The first portion may substantially correspond to a predetermined exposure region of a patterning device for use with the pellicle.

The first portion may be substantially the same size as the predetermined exposure region of the patterning device.

The second portion may be at a periphery of the membrane.

The pellicle may comprise a border at the periphery of the membrane, wherein the second portion may coincide with the border. However, it is to be understood that the border is generally not part of the second portion, nor is the border considered herein a protective region. The border is generally non-transmissive of EUV radiation, and its function is solely to support the membrane at the periphery from buckling or breaking in contact with a frame. Only in the exceptional case when the border is so thin as to transmit at least 10% of EUV radiation and can be illuminated with the exposure radiation, then the border can be regarded a protective region. For example, the pellicle comprises a border at the periphery of the membrane, wherein the second portion coincides in size with the border, and the border is provided on an opposite side of the membrane than the protective portion.

The protective portion may comprise a material that is suitable to protect the second portion of the membrane from hydrogen etching.

The protective portion may be on at least one of: a first side and an opposite second side of the membrane; and an edge of the membrane.

The protective portion may be on only one side of the membrane (e.g. a front side of the membrane).

The first side of the membrane may be a front side of the membrane. The second side of the membrane may be a back side of the membrane.

The protective portion may comprise a material (also referred as a capping material) covering the second portion.

The capping material may comprise at least one of: carbon nanotubes, graphene, amorphous carbon, (low melting point metals), molybdenum (Mo), yttrium (Y), yttrium oxide (YₐO_{b}), aluminium oxide (Al₂O₃) (AlO₂), hafnium oxide (HfO₂), zirconium oxide (ZrO₂), ruthenium (Ru), platinum (Pt), gold (Au), zirconium nitride (ZrN), aluminium (Al) zirconium (Zr), silicon (Si), silicon carbide (SiC) silicon oxide (SiOₐ), boron (B), boron carbide (B₄C), boron nitride (BN), titanium (Ti), and titanium nitride (TiN).

The membrane may comprise the protective portion and the protective portion may comprise the same material as the first and second portions.

The pellicle may comprise a pellicle frame and the protective portion comprises a shield, wherein the shield may be supported by the pellicle frame.

The shield may be separated from the membrane by a gap, preferably wherein the gap is less than 1000 μm or less than 2000 μm.

The shield may be at least one of: substantially transparent to heater radiation, substantially transparent to IR radiation, substantially transparent to DUV radiation, and inert in plasma.

The shield may comprise at least one of: aluminium oxide (Al₂O₃), sapphire, aluminium oxide (Al₂O₃) coated glass, and sapphire coated glass.

The protective portion may comprise a plurality of shields, a first shield on a first side of the membrane and a second shield on an opposite second side of the membrane.

The first portion may substantially correspond to an extended region greater than the predetermined exposure region of a patterning device for use with the pellicle.

The extended region may extend to a predetermined distance outwardly from the predetermined exposure region of the patterning device.

The extended region may extend outwardly from the predetermined exposure region of the patterning device at least one of 1000 μm, in a range of 1000-2000 μm and in a range of 1000-4000 μm.

The second portion may extend to a predetermined distance inwardly with respect to an inward edge of a pellicle frame and/or a border at the periphery of the membrane.

The second portion may extend inwardly with respect to the inward edge of the pellicle frame and/or the border: at least 1300 μm, at least 1500 μm, at least 2300 μm, in a range of 1300 μm-2300 μm.

The membrane may comprise a carbon-based material, such as carbon nanotubes.

According to a second aspect, there is provided a lithographic apparatus operable to form an image of a patterning device on a substrate using a radiation beam, the lithographic apparatus comprising a pellicle disposed in a path of the radiation beam, the pellicle as described above.

According to a third aspect, there is provided a method for forming a pellicle for use in a lithographic apparatus, the method comprising: providing a membrane comprising a first portion and a second portion, providing a protective portion at the second portion on at least one side of the membrane. For example, the method for forming a pellicle for use in a lithographic apparatus comprises: providing a membrane comprising carbon nanotubes, the membrane comprising a first portion and a second portion, providing a protective portion at the second portion on at least one side of the membrane, wherein the protective portion comprises a material that is suitable to protect the second portion of the membrane from etching.

The method may further comprise providing the protective portion using an additive method or a subtractive method.

The method may further comprise providing the protective portion using an additive method, wherein the protective portion may comprise a capping material; depositing the capping material over the second portion to cover the second portion.

The method may further comprise masking the first portion using a masking element.

The masking element may substantially correspond to a predetermined exposure region of a patterning device for use with the pellicle.

The method may further comprise depositing the capping material using at least one of: thermal evaporation, e-beam evaporation, e-beam deposition, pulsed laser deposition, atomic layer deposition and remote plasma sputtering.

The method may further comprise providing the protective portion using a subtractive method, wherein the protective portion may comprise a capping material; applying the capping material over the first portion and the second portion, and removing the capping material from the first portion.

The method may further comprise removing the capping material from the first portion using at least one of: laser annealing, laser ablating, reactive ion etching, and lift-off.

The capping material may be a volatile or thermally unstable material for being desorbed by EUV radiation.

The method may further comprise providing the protective portion using a subtractive method including providing the membrane with a thickness, and partially removing the first portion to reduce the thickness of the first portion, wherein the membrane may comprise the protective portion and the protective portion may comprise the same material as the first and second portions.

The method may further comprise etching the first portion in hydrogen plasma.

The method may further comprise providing the protective portion on at least one of: a first side and an opposite second side of the membrane; and an edge of the membrane.

The method may further comprise providing the first portion to substantially correspond to a predetermined exposure region of a patterning device for use with the pellicle.

The method may further comprise providing the protective portion during at least one of fabrication of the pellicle, fabrication of a patterning device and fabrication of a substrate.

The method may further comprise providing a pellicle frame, wherein the protective portion may comprises a shield and the pellicle frame may support the shield.

The method may further comprise separating the shield from the membrane by a gap.

The method may further comprise providing a plurality of shields, a first shield on a first side of the membrane and a second shield on an opposite second side of the membrane.

The method may further comprise providing the first portion to substantially correspond to an extended region greater than the predetermined exposure region of a patterning device for use with the pellicle.

### BRIEF DESCRIPTION OF THE DRAWINGS

Embodiments of the invention will now be described, by way of example only, with reference to the accompanying schematic drawings, in which:

FIG. 1 depicts a lithographic system comprising a lithographic apparatus and a radiation source;

FIG. 2 schematically depicts a cross section of a pellicle and a patterning device according to an embodiment of the present disclosure;

FIG. 3 schematically depicts a plan view of a pellicle of FIG. 2;

FIG. 4 shows an expected etching rate for hydrogen etching of carbon as a function of temperature for a hydrogen ion flux of 1.5·1019 m−2·s−1 for four different ion energies: 5 eV, 10 eV, 20 eV and 30 eV; FIG. 4 also shows an sp3 carbon concentration as a function of temperature;

FIG. 5 is a schematic illustration of a method for forming a pellicle according to an embodiment of the present disclosure; and

FIG. 6 schematically depicts a cross section of a pellicle and a patterning device according to another embodiment of the present disclosure.

### DETAILED DESCRIPTION

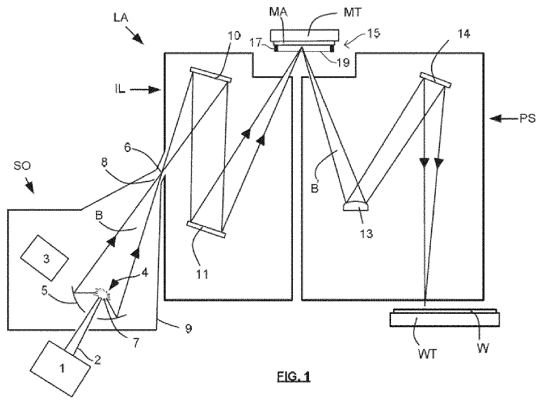

FIG. 1 shows a lithographic system including a pellicle 15. The lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA held by the support structure MT. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11. The patterning device MA is protected by a pellicle 15. The pellicle 15 includes a membrane 19 that is held in place by a pellicle frame 17. The membrane 19 and the pellicle frame 17 together form the pellicle 15.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13,14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13,14 in FIG. 1, the projection system PS may include a different number of mirrors (e.g., six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO shown in FIG. 1 is, for example, of a type which may be referred to as a laser produced plasma (LPP) source. A laser system 1, which may, for example, include a CO₂ laser, is arranged to deposit energy via a laser beam 2 into a fuel, such as tin (Sn) which is provided from, e.g., a fuel emitter 3. Although tin is referred to in the following description, any suitable fuel may be used. The fuel may, for example, be in liquid form, and may, for example, be a metal or alloy. The fuel emitter 3 may comprise a nozzle configured to direct tin, e.g. in the form of droplets, along a trajectory towards a plasma formation region 4. The laser beam 2 is incident upon the tin at the plasma formation region 4. The deposition of laser energy into the tin creates a tin plasma 7 at the plasma formation region 4. Radiation, including EUV radiation, is emitted from the plasma 7 during de-excitation and recombination of electrons with ions of the plasma.

The EUV radiation from the plasma is collected and focused by a collector 5. Collector 5 comprises, for example, a near-normal incidence radiation collector 5 (sometimes referred to more generally as a normal-incidence radiation collector). The collector 5 may have a multilayer mirror structure which is arranged to reflect EUV radiation (e.g., EUV radiation having a desired wavelength such as 13.5 nm). The collector 5 may have an ellipsoidal configuration, having two focal points. A first one of the focal points may be at the plasma formation region 4, and a second one of the focal points may be at an intermediate focus 6, as discussed below.

The laser system 1 may be spatially separated from the radiation source SO. Where this is the case, the laser beam 2 may be passed from the laser system 1 to the radiation source SO with the aid of a beam delivery system (not shown) comprising, for example, suitable directing mirrors and/or a beam expander, and/or other optics. The laser system 1, the radiation source SO and the beam delivery system may together be considered to be a radiation system.

Radiation that is reflected by the collector 5 forms the EUV radiation beam B. The EUV radiation beam B is focused at intermediate focus 6 to form an image at the intermediate focus 6 of the plasma present at the plasma formation region 4. The image at the intermediate focus 6 acts as a virtual radiation source for the illumination system IL. The radiation source SO is arranged such that the intermediate focus 6 is located at or near to an opening 8 in an enclosing structure 9 of the radiation source SO.

Although FIG. 1 depicts the radiation source SO as a laser produced plasma (LPP) source, any suitable source such as a discharge produced plasma (DPP) source or a free electron laser (FEL) may be used to generate EUV radiation.

As was described briefly above, the pellicle 15 includes the membrane 19 that is provided adjacent to the patterning device MA. The membrane 19 is provided in the path of the radiation beam B such that radiation beam B passes through the membrane 19 both as it approaches the patterning device MA from the illumination system IL and as it is reflected by the patterning device MA towards the projection system PS. The membrane (or thin film) 19 is substantially transparent to EUV radiation (although it will absorb a small amount of EUV radiation). By EUV transparent membrane or a film substantially transparent for EUV radiation herein is meant that the membrane 19 is transmissive for at least 65% of the EUV radiation, preferably at least 80% and more preferably at least 90% of the EUV radiation. The membrane 19 acts to protect the patterning device MA from particle contamination. The membrane 19 may be herein referred to as an EUV transparent membrane.

Whilst efforts may be made to maintain a clean environment inside the lithographic apparatus LA, particles may still be present inside the lithographic apparatus LA. In the absence of the membrane 19, particles may be deposited onto the patterning device MA. Particles on the patterning device MA may disadvantageously affect the pattern that is imparted to the radiation beam B and therefore the pattern that is transferred to the substrate W. The membrane 19 provides a barrier between the patterning device MA and the environment in the lithographic apparatus LA in order to prevent particles from being deposited on the patterning device MA.

In use, the membrane 19 is positioned at a distance from the patterning device MA that is sufficient that any particles that are incident upon the surface of the membrane 19 are not in the focal plane of the radiation beam B. This separation between the membrane 19 and the patterning device MA, acts to reduce the extent to which any particles on the surface of the membrane 19 impart a pattern to the radiation beam B. It will be appreciated that where a particle is present in the beam of radiation B, but at a position that is not in a focal plane of the beam of radiation B (i.e., not at the surface of the patterning device MA), then any image of the particle will not be in focus at the surface of the substrate W. In the absence of other considerations it may be desirable to position the membrane 19 a considerable distance away from the patterning device MA. However, in practice the space which is available in the lithographic apparatus LA to accommodate the pellicle 15 is limited due to the presence of other components. In some embodiments, the separation between the membrane 19 and the patterning device MA may, for example, be approximately between 1 mm and 10 mm, for example between 1 mm and 5 mm, for example between 2 mm and 3 mm (e.g. around 2.5 mm), for example between 2 mm and 2.5 mm. In some embodiments, a separation between the membrane 19 and the patterning device MA may be adjustable.

The pellicle 15 may comprise a border portion. The border portion of the pellicle 15 may be hollow and generally rectangular and the membrane 19 may be bounded by the border portion. As known in the art, one type of pellicle may be formed by deposition of one or more thin layers of material on a generally rectangular silicon substrate. The silicon substrate supports the one or more thin layers during this stage of the construction of the pellicle. Once a desired or target thickness and composition of layers has been applied, a central portion of the silicon substrate is removed by etching (this may be referred to as back etching). A peripheral portion of the rectangular silicon substrate is not etched (or alternatively is etched to a lesser extent than the central portion). This peripheral portion forms the border portion of the final pellicle while the one or more thin layers form the membrane of the pellicle (which is bordered by the border portion). The border portion of the pellicle may be formed from silicon.

Some embodiments of the present disclosure relate to a new type of pellicle and methods of forming such a pellicle.

The pellicle 15 (for example comprising a border) may require some support from the more rigid pellicle frame 17. The pellicle frame 17 may provide two functions. First, the pellicle frame 17 may support and tension the membrane 19. Second, the pellicle frame 17 may facilitate connection of the pellicle 15 to the patterning device (reticle or photomask) MA. It one known arrangement, the pellicle frame 17 may comprise a main, generally rectangular body portion which is glued to the border portion of the pellicle 15 and titanium attachment mechanisms that are glued to the side of this main body. Intermediate fixing members (known as studs) are affixed to the patterning device (reticle) MA. The intermediate fixing members (studs) on the patterning device (reticle) MA may engage (for example releasably engage) with the attachment members of the pellicle frame 17.

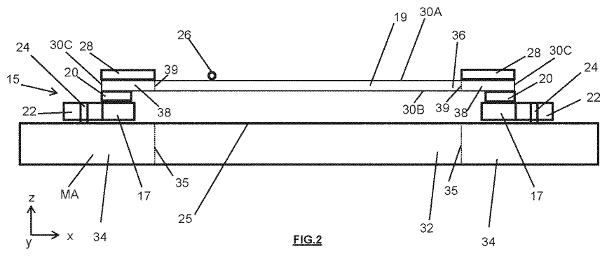

FIG. 2 is a more detailed cross-sectional view of the pellicle 15 and the patterning device MA shown in FIG. 1. The pellicle 15 comprises the pellicle frame 17 (hereinafter referred to as frame) and the membrane 19. Although not shown in FIG. 1, the pellicle 15 comprises a pellicle border 20. The border 20 can optionally be integral with, comprised in or physically separate from the membrane 19. The border 20 may be significantly thicker than the main portion of the membrane 19 and may be located around an outer perimeter (periphery) of the membrane 19. It is this border 20 which is attached to the frame 17. The frame 17 supports the pellicle 15 around a perimeter portion of the membrane 19 via the border 20. The border 20 may be glued to the frame 17 or may be attached in another manner. In embodiments, the membrane 19 and the border 20 are fabricated together (i.e. at the same time). In some embodiments, the border 20 may be integrated with the frame 17. It will be appreciated that, in other embodiments, the pellicle 15 may not comprise a border, i.e. the membrane 19 may be formed directly on the frame 17.

The frame 17 may include an engagement mechanism 22 configured to allow the frame 17 to be removably attachable to the patterning device MA (i.e. to allow the frame 17 to be attachable to and detachable from the patterning device MA). The engagement mechanism 22 is configured to engage with an attachment member 24 provided on the patterning device MA. The attachment member 24 may, for example, be a protrusion or a stud which extends from the patterning device MA. The engagement mechanism 22 may, for example, comprise a locking member (not shown) which engages with the attachment member 24 and secures the frame 17 to the patterning device MA.

A plurality of engagement mechanisms 22 and associated attachment members 24 may be provided. The engagement mechanisms 22 may be distributed around the frame 17. Associated attachment members may be distributed around the perimeter of the patterning device MA.

The patterning device MA has a patterned surface 25. A contamination particle 26 is schematically shown. The contamination particle 26 is incident upon the membrane 19 and is held by the membrane 19. The membrane 19 holds the contamination particle 26 sufficiently far from the patterned surface 21 of the mask MA so that it is not imaged onto substrates by the lithographic apparatus LA. A pellicle 15 may allow a mask pattern (on the patterning device MA) to be provided which is protected from contamination by the pellicle 15 such that the pattern produced using the mask remains substantially defect free during use.

The pellicle 15 may be constructed by depositing the membrane 19 directly on top of a substrate which is to provide the border 20. After depositing of the membrane 19 of the pellicle 15, the substrate may be selectively back-etched to remove a central portion of the substrate and leave only an outer perimeter to form the border 20 to support the membrane 19. Alternatively, material for the border 20 may be deposited. This may be better as it avoids the challenge and stress of selective removal.

The pellicle 15 may be suitable for use adjacent to the reticle MA within an EUV lithographic apparatus LA. In use, such a (reflective) MA is illuminated with EUV radiation, for example from the illumination system IL. It will be appreciated that the reticle MA is configured to impart the radiation beam received from the illumination system IL with a pattern in its cross-section to form a patterned radiation beam. A projection system collects the (reflected) patterned radiation beam and forms a (diffraction-limited) image of the reticle MA on a substrate (for example a resist coated silicon wafer). Any contamination on the reticle MA will, in general, alter the image formed on the substrate, leading to printing errors.

To avoid particle contamination of the reticles MA, the pellicle 15 is used to protect the reticle MA. As described, the pellicle 15 is disposed in front of the reticle MA and prevents particles 26 from the landing on the reticle MA. The membrane 19 of the pellicle 15 is disposed such that it is not sharply imaged by the projection system and therefore particles on the membrane 19 do not interfere with the imaging process. It is desirable for the membrane 19 to be sufficiently strong that it stops particles 26 from impinging on the reticle MA that would cause unacceptable printing errors but as thin as possible to reduce the absorption of EUV radiation by the membrane 19.

The pellicle 15 comprises a protective portion 28. In this embodiment, the protective portion 28 is provided at a periphery of, and on a first side 30A of, the membrane 19. The first side 30A may be considered to be a front side. That is, the side that the EUV radiation (EUV radiation beam B) is incident on from the radiation source SO and/or illumination system IL. The first side 30A is opposite the side of the membrane 19 facing the patterning device MA in use. The first side 30A is opposite the side of the membrane 19 attached to a pellicle frame 17. The border 20 is provided at a periphery of, and on a second side 30B of, the membrane 19. The second side 30B may be considered to be a back side. The second side 30B faces the patterning device MA in use. The second side 30B is attached to a pellicle frame 17 (i.e. via the border 20). In other embodiments, a (or the) protective portion may, alternatively or additionally, be provided on the back side of the membrane. For example, both sides (front [first] and back [second]) of the membrane may have protective portions on part of their surfaces. Furthermore, a protective portion may, alternatively or additionally, be provided on edges 30C of the membrane (i.e. edges that extend in the z direction). In addition, in embodiments (e.g. with a CNT membrane), a protective portion may be conformal (i.e. coated around the CNT tubes) or interstitial (i.e. inside spaces in the membrane). In general, the protective portion may be provided on any portion of the membrane that may need to be protected, e.g. from etching. In embodiments, the protective potion on the front side of the membrane may cover a different area to the protective portion on the back side of the membrane. The protective portion on the back side of the membrane may also cover the border.

The patterning device MA comprises an exposure region 32 and a non-exposure region 34 (delimited as shown by the dotted lines 35). That is, during imaging, the exposure region 32 will receive EUV radiation and the non-exposure region 34 will not. The exposure region 32 has an area (in the xy plane) which forms at least part of the patterned surface 25. The exposure region 32 may be predetermined based on the specific field size that is chosen or desired. The exposure region 32 may be a chosen mask exposure field. The exposure region 32 may be referred to as the mask imaging field. The exposure region 32 may be continuous, i.e. is a single area. The exposure region 32 may include a plurality of dies (not shown), with separation for kerf or metrology or a single die. The dies may be clustered. If it was considered that there were exposure regions for separate dies, the exposure regions may be contiguous.

The membrane 19 comprises a first portion 36 and a second portion 38 (delimited as shown by the dotted lines 39). The first portion 36 has a first area and the second portion 38 has a second area (i.e. in the xy plane). In embodiments, the first portion 36 corresponds to the predetermined exposure region 32 of the patterning device MA. That is, the first portion 36 is substantially the same size (i.e. has the same area) as the exposure region 32. Thus, similarly, the second portion 38 extends inwardly (towards the centre in the x direction) to the same extent as the non-exposure region 34. It will be appreciated that the non-exposure region 34 may extend further outwardly (away from the centre in the x direction) than the second portion 38 since the patterning device MA may be larger in the x direction than the membrane 19.

It will be appreciated that the first portion 36 may also be considered to be an exposed region and the second portion 38 may also be considered to be an unexposed region as only the first portion will receive EUV radiation during imaging. However, in some embodiments, the distinction between first portion 36 and second portion 38 may relate to the amount of EUV imaging radiation that is incident thereon. For example, the first portion 36 may receive a full (100%) of the maximum EUV power density whereas the second portion 38 may only receive a fraction (e.g. 50%) of the maximum EUV power density. In general, the second portion 38, in use, may receive EUV imaging radiation, but may only receive a fraction of the EUV imaging radiation (when compared to the amount received by the first portion 36).

As shown, the protective portion 28 is at the second portion 38 on a side of the membrane 19 (i.e. the front side of the membrane 19). The protective portion 28 is not at the first portion 36. In other words, the protective portion 28 is only on the second portion 38 and is not on the first portion 36. The protective portion 28 covers the second portion 38 and does not cover the first portion 36. It may be considered that the protective portion 28 only partially covers the membrane 19. Furthermore, that the protective portion 28 only covers the non-imaging area (i.e. the area of the second portion 38).

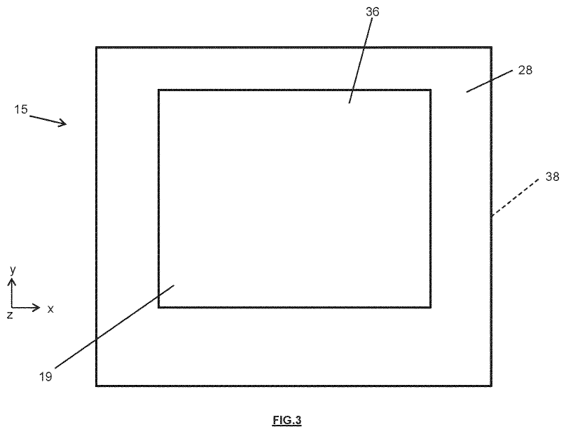

FIG. 3 is a plan (front side) view of the pellicle 15 shown in FIG. 2. The frame 17 and patterning device MA are not included for clarity. The first portion 36 of the membrane 19 forms a rectangular shape substantially in the centre of the membrane 19. The second portion 38 is underneath the protective portion 28 in FIG. 2 so cannot be seen in this view. However, it will be understood that the second portion 38 surrounds the first portion 36 on each side (wrt the xy plane). The protective portion 28 is shown covering the second portion 38 (i.e. covering the same area). It will be appreciated that this is just an example and other sizes and/or shapes of the first portion, second portion and/or protective portion may be provided.

The pellicle 15 shown in FIGS. 2 and 3 is particularly advantageous, as now discussed.

One particularly promising carbon-based material for use as a pellicle membrane in an EUV lithographic apparatus is a fabric or membrane formed from carbon nanotubes (CNTs). Such a CNT pellicle is a porous material and, therefore, can provide very high EUV transmission (of >98%). Furthermore, CNT pellicles also provide very good mechanical stability and can therefore be fabricated at small thicknesses, whilst remaining robust against mechanical failure. However, a low pressure hydrogen gas is typically provided within the lithographic apparatus, which forms a hydrogen plasma in the presence of the EUV radiation (during exposure). The plasma is present in the lithographic apparatus LA specifically to remove carbon deposited in the vacuum onto mirror surfaces. However, this can lead to etching of the CNT membranes themselves. It has been found that hydrogen ions and hydrogen free radicals from the hydrogen plasma can etch pellicles formed from CNTs, limiting the potential lifetime of the pellicle and blocking commercial implementation of CNT pellicles.

In order to mitigate such etching of CNT pellicles, it has previously been proposed to provide such CNT pellicles with a protecting, capping layer (a coating). However, it is desirable to minimize the absorption of EUV radiation by the pellicle and including a capping layer will increase the EUV transmission loss. In addition, coatings on CNT membranes are sensitive to temperature and will not survive (at least for a desired amount of time) in a high-source power lithographic apparatus LA. Furthermore, a difference between the refractive indices of carbon and suitable capping layers is typically larger than a difference between the refractive indices of carbon and the vacuum. Therefore, such a capping layer will result in an increase in EUV flare (scattered light), which is undesirable as it reduces image quality. For the CNT pellicle or any pellicle based on carbon, the hydrogen plasma in the lithographic apparatus LA will eventually limit lifetime.

The interaction of hydrogen ions with carbon materials is described quantitatively in the following two published papers, the contents of which are hereby incorporated by reference: (1) J. Roth, C. García-Rosales, “Analytic description of the chemical erosion of graphite by hydrogen ions”, Nucl. Fusion 1996, 36/12, 1647-1659; and (2) J. Roth, C. García-Rosales, “Corrigendum—Analytic description of the chemical erosion of graphite by hydrogen ions”, Nucl. Fusion 1997, 37, 897. This quantitative description of the interaction of hydrogen ions with carbon materials may be referred to as Roth-García-Rosales (RGR) model. The RGR model can be used to predict an etch yield of carbon materials as function of the temperature for the typical hydrogen ion energies encountered within the lithographic apparatus such as, for example, ion energies form 1-30 eV. Within an EUV lithographic apparatus a typical hydrogen ion flux incident on the pellicle may be of the order of 1·1019 m−2·s−1. Within an EUV lithographic apparatus a typical hydrogen ion flux incident on the pellicle may be within a couple of orders of magnitude of 1·1019 m−2·s−1 (for example from 101 8m−2·s−1 to 1020 m−2·s−1).

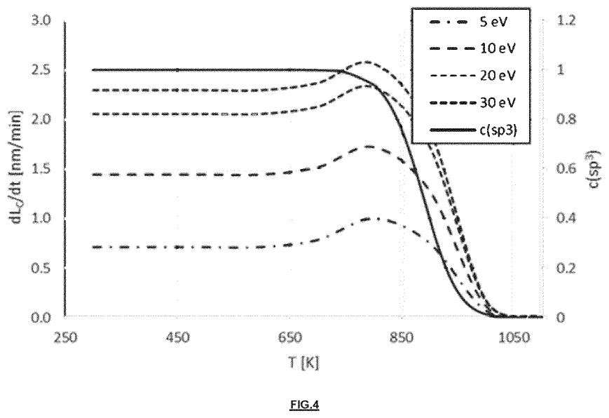

FIG. 4 shows an expected etching rate for hydrogen etching of carbon as a function of temperature for a hydrogen ion flux of 1.5·1019 m−2·s−1 for four different ion energies: 5 eV, 10 eV, 20 e V and 30 eV. The figure shows an sp3 carbon concentration as a function of temperature. It can be seen that for these typical ambient conditions in the lithographic apparatus LA, it is expected that for a pellicle formed purely from CNTs the hydrogen etching rate of the pellicle falls to a negligible level at a temperature of around 1050 K. However, it will be appreciated by the skilled person that under different conditions a different minimum temperature may be desirable.

The etching of carbon by hydrogen ions and free radicals can be temperature dependent. In particular, the carbon etching rate can be higher at low and intermediate temperatures but the carbon etching rate falls to a negligible level at sufficiently high temperatures. Also, while a central portion of a membrane 19 within an EUV lithographic scanner LA may reach a sufficiently high temperature that hydrogen etching will be negligible (at least part of the time), a periphery of the membrane 19 will typically remain below this temperature and will therefore be more susceptible to hydrogen etching. That is, the CNT membranes will be heated to a temperature that actually limits the hydrogen plasma etch rate. This essentially creates multiple zones for the membrane 19, which we have referred to as the first portion 36 and the second portion 38. Although, in embodiments, the first portion 36 and the second portion 38 are, respectively, relatively hotter (exposed) and relatively cooler (unexposed) areas, it will be appreciated that, in other embodiments, the first portion 36 and second portion 38 (different zones) may be defined by other characteristics. Furthermore, the different zones (i.e. first portion 36 and second portion 38) may have different sizes and shapes as required. In embodiments, there may be a plurality of first portions 36 and/or a plurality of second portions 38. They may be separated, e.g. two first portions 36 may be separated by a second portion 38 and vice versa.

To maximize lifetime in the scanner and performance, it is important to tailor each CNT pellicle zone (or portion) for its use. The most-exposed region (the first portion 36) of the membrane will be over the reticle exposure field. The least-exposed region (the second portion 38) is over the frame region and has less stringent optical requirements.

Advantageously, the pellicle 15 shown in FIGS. 2 and 3 provides the additional protective portion 28 on the second portion 38 of (a front side 30A of) the membrane 19 that: (a) is most at risk from hydrogen etching; and (b) in use, does not receive EUV radiation. This allows the lifetime of the pellicle 15 to be increased without affecting the performance of the lithographic apparatus LA.

In some embodiments, the protective portion 28 is provided on a portion of the membrane 19 that, in use, does not receive EUV radiation (during imaging [exposure]). The first portion 36 is exposed to EUV radiation (during imaging) and thus is heated. The second portion 38 is not exposed to EUV radiation (during imaging) and consequently is not heated. Thus, the second portion 38 needs to be protected to extend lifetime. It will be appreciated that the second portion 38 does not necessarily need to be exactly lined up with the exposure region 32 of the patterning device MA, i.e. it may be substantially corresponding. For example, due to heat transfer from the EUV imaging radiation, there may be part of the membrane 19 a distance away (e.g. 0.25-2 mm) from the part that is exposed to the (full) EUV imaging radiation, that does not suffer from etching (or at least suffers to an extent that is not problematic for lifetime considerations). It will be understood that where reference is made to the second portion 38 not receiving (full EUV imaging radiation) or the first portion 36 corresponding to a predetermined exposure region 32 of a patterning device MA, the position of the second portion 38, and thus the position of the protective portion 28, may take these distances into account. That is, the second portion 38 may start exactly where the exposure region ends or may start a distance (e.g. 0.25-2 mm) away from the exposure region (i.e. towards the edge of the membrane 19) that takes into account this heat transfer.

The protective portion 28 may be provided on the membrane 19 such that it coincides in size with the border 20. That is, the protective portion 28 overlaps with the border 20, but the border 20 is provided on the opposite side 30B of the membrane 19. For clarity, border 20 has a support function for the membrane 19, whereas the protective portion 28 has the function to protect a second portion of membrane 19 (which is not, or only partially illuminated with EUV radiation) against being etched in a plasma environment created around the membrane 18 during EUV exposure. However, the protective portion 28 may also have a different size than the border and partially coincide or even not coincide with the border, while still covering the second membrane region which is outside of the exposure first region. Therefore, the material of the protective portion 28 may be chosen such that, besides providing resistance against etching it also may be partially transparent to EUV radiation.

When the protective portion 28 does not coincide in size with the border 20, since the protective portion 28 covers all of the second portion 38 and the border 20 does not cover all of the second portion 38 (on the other side), the protective portion 28 extends into part of the membrane 19 that does not coincide with the border 20. That is, the protective portion 28 also extends partially inwards onto a region of the membrane 19 that is not attached to the border 20. In some embodiments, the protective portion may be provided during pellicle manufacturing, rather than during manufacture of the mask. During pellicle manufacturing the pellicle may not have been matched to a reticle or field yet. However, during pellicle manufacturing, the pellicle may be produced with certain standard field size, with the periphery coated with the protective portion accordingly, such as 100%, 80% etc.

In some embodiments, the protective portion 28 may be formed from a material that is suitable to protect a portion of the membrane 19 to which it is attached from hydrogen etching. For such embodiments, the protective portion 28 may comprise a capping material (which may be referred to as a coating). The capping material may be considered to cover the second portion 38. The capping material may only cover the second portion 38, i.e. may not cover the first portion 36. It may be considered that the coating only partially covers the membrane 19. The coating may only cover the non-imaging area of the membrane 19 (i.e. the second area of the second portion 38.) The coating is only applied outside the imaging field. The coating may not cover the imaging area of the membrane 19 (i.e. the first area of the first portion 36.) In embodiments, the protective portion 28 may be provided on the periphery on both (all) sides, i.e. the first side 30A and second side 30B (and edges 30C) of the membrane 19. This may provide increased protection when compared to the protective portion 28 only being on the first side 30A of the membrane 19.

The capping material may comprise any of the following materials either alone or in combination: carbon nanotubes, graphene, amorphous carbon, (low melting point metals (e.g. temperature below 600 C), molybdenum (Mo), yttrium (Y), yttrium oxide (YₐO_{b}), aluminium oxide (Al₂O₃) (AlO₂), hafnium oxide (HfO₂), zirconium oxide (ZrO₂), ruthenium (Ru), platinum (Pt), gold (Au), zirconium nitride (ZrN), aluminium (Al), zirconium (Zr), silicon (Si), silicon carbide (SiC) silicon oxide (SiOₐ), boron (B), boron carbide (B₄C), boron nitride (BN), titanium (Ti), titanium nitride (TiN). It will be appreciated that these are just examples and other materials may be used. The capping material may comprise a plurality of sublayers formed from different materials.

It will be appreciated that a greater thickness of such a capping material may be provided in the protective portion 28 (i.e. over the second portion 38) relative to the central first portion 36 of the membrane 19). That is, there may be some capping material over the first portion 36 in some embodiments. In some embodiments, there may be a relatively thick or thin coating in the exposed region and a relatively thick coating in the periphery. In general, there may be different extents of coverage and gradients may be possible. More generally, in embodiments, the first protective portion may be at or on the first portion but only to a lesser extent than at or on the second portion.

In some embodiments, the protective portion 28 may be formed from the same material as a bulk of the membrane 19. For such embodiments, the protective portion 28 may be an increased thickness of the bulk material (for example a CNT membrane), which may act as a sacrificial portion providing an increased thickness to be etched by the hydrogen. In this embodiment, it may be considered that the membrane 19 comprises the protective portion 28 and the protective portion 28 comprises the same material (e.g. carbon nanotubes) as the first portion 36 and the second portion 38.

In some embodiments, the membrane 19 may comprise a porous membrane. In some embodiments, the membrane 19 comprises nanotubes. For example, the membrane 19 may be a fabric formed from CNTs. This may be referred to as a carbon nanotube membrane. This is a particularly promising material for use as a pellicle membrane in an EUV lithographic apparatus.

There may a requirement that the first portion 36 provides >90% EUV transmission whereas the second portion 38 may only need to provide >80% EUV transmission. Furthermore, there may be requirement that the first portion 36 is tolerant (can withstand) high temperatures (>700 deg C) whereas the second portion 38 may only need to be tolerant to (withstand) lower temperatures (>500 deg C). There may be structures in a frame of the patterning device MA that are used for e.g. correction, alignment etc, and that may need to be visible to metrology sensors and so the second portion 38 may need to be transparent to EUV radiation to some extent, but not to the extent of the first portion 36. Furthermore, this EUV radiation that may be incident on the second portion 38 may be different from the EUV radiation used for imaging (i.e. EUV imaging radiation. For example, it may be not at the same high power as the EUV radiation for imaging, or may be a different wavelength and reduced dose relative to the EUV imaging radiation, and so will not damage (or destroy) the protective portion 28 (capping material).

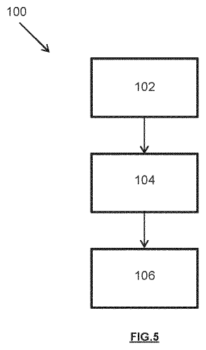

Some embodiments of the present disclosure relate to a method of forming a pellicle 15 for use in a lithographic apparatus such as the lithographic apparatus LA shown in FIG. 1. Such a method 100 is illustrated schematically in FIG. 5.

The method 100 comprises a step 102 of providing a membrane 19 comprising a first portion 36 and a second portion 38.

The method further comprises providing a protective portion 28 at the second portion 38 on a side or sides of the membrane 19, which may be by several different methods as will be explained.

The protective portion 28 may be provided by an additive method or a subtractive method as will be described in more detail.

In general, the method may comprise providing the first portion 36 to correspond to the predetermined exposure region 32 of the patterning device MA (i.e. that is for use with the pellicle 15).

An important aspect is that the pellicle 15 may be modified (i.e. by providing the protective portion 28) at the point of use (e.g. during fabrication of the patterning device MA and/or fabrication of a substrate W). This is once the reticle field size (e.g. max 104×132 mm² or smaller than full field size) associated with the mask (patterning device MA) is identified. In this case, the pellicle 15 may be selected and treated for desired design (with specific field) size. The treatment may be considered to be providing the pellicle 15 with the protective portion 28 at the second portion 38.

Mask fabrication may include e.g. qualifying the patterning device with CD measure, defect inspection etc; and mounting the pellicle onto the patterning device, which may include re-qualifying mask. Substrate (wafer) fabrication may include e.g. qualifying the pattering device with inspection and/or substrate exposures. The pellicle treatment (i.e. selecting and treating for desired design size) may be done at substrate W fabrication if the pellicle 15 is mounted on the patterning device MA there.

In other embodiments, the pellicle 15 may be provided with the protective portion 28 during fabrication of the pellicle 15. This may be when the membrane 19 is fabricated and the membrane 19 is attached to the frame 17. The membrane 19 may be fabricated or procured on a border 20.

For the additive method, the protective portion 28 may comprise a capping material (e.g. formed of a material such as those method above)—this may be referred to as a coating. In some embodiments, the method 100 may comprise a step 104 of masking the first portion 36 using a masking element. This means that the second portion 38 may be covered with the capping material without also covering the first portion 36. The masking element may be a shadow mask. Since the field size is mask specific then the shadow mask is adapted to chosen mask field size. In embodiments, the masking element corresponds to the predetermined exposure region 32 of the patterning device MA (i.e. that is for use with the pellicle 15).

The method 100 may comprise a step 106 of depositing the capping material over the second portion 38 (and the masking element) to cover the second portion 38. This results in the protective portion 28 being at the second portion 38 due to the first portion 36 being masked in step 104.

The capping material may be deposited using at least one of: thermal evaporation, e-beam evaporation, e-beam deposition, pulsed laser deposition, atomic layer deposition and remote plasma sputtering.

For the subtractive method, the protective portion 28 may comprise a capping material (e.g. formed of a material such as those method above)—this may be referred to as a coating. The method may comprise applying the capping material over the first portion 36 and the second portion 38, and then removing the capping material from the first portion 36. Thus, the capping material would only be left over the second portion 38 (the cold area). This results in the protective portion 28 being at the second portion 38. That is, the membrane 19 is fully coated and then some of the coating (over the first portion 36) is selectively removed to leave only a partial coating.

The method may further comprise laser annealing, laser ablating, reactive ion etching, and/or lift-off the capping material from the first portion 36. This may be at high temperatures (e.g. a minimum of 500 C, 600 C or, more practically, 900 C). It will be appreciated that these are just examples and other temperatures may be applicable.

The capping material may be a volatile or thermally unstable material suitable for being desorbed by EUV radiation (e.g. in a range of 200 W to a few kWs, above 200 W, above 600 W or above 1 kW EUV source power). For example, this may be during imaging (e.g. during exposure of the first field in the EUV lithographic apparatus) In embodiments, this may be during a “pre-sweep” because actual images are printed, since those require very stable conditions. Materials such as amorphous carbon (thick layer) or low melting point metals (e.g. Boron) show dewetting behaviour above a certain temperature where the compound desorbs and thus may be suitable for use as the capping material when using this method. For example, the temperature where the compound desorbs may be 500 C, 600 C, 700 C, 800 C, 900 C, or lower or higher depending on the material.

For the subtractive method, the protective portion 28 may comprise the same material (e.g. carbon nanotubes) as the first portion 36 and the second portion 38. In this case, it may be considered that the membrane 19 comprises the protective portion 28.

The method may comprise providing the membrane 19 with a thickness (in the z direction) and then partially removing the first portion 36 to reduce the thickness of the first portion 36. The thickness of the protective portion 28 may be considered to be equivalent to the thickness that has been removed from the first portion 36. That is, after the removal, it may be considered that the first portion 36 has a reduced thickness with the protective portion 28 having a thickness which is equal to that removed from the first portion 36. It may be considered that the second portion 38 comprises the protective portion 28 (i.e. that the total thickness of the second portion 38 (including the protective portion 28) is equal to the thickness of the membrane 19 before part of the first portion 36 is removed.

The method may comprise etching the first portion 36 in hydrogen plasma, e.g. an RF plasma etch.

The protective portion 28 may be considered to be a sacrificial portion, i.e. providing an increased thickness to be etched by the hydrogen so that the second portion 38 does not get etched by the hydrogen.

The provision of the protective portion 28 only on the second portion 38, which is outside the imaging area, has an advantage that the protective portion 28 protects the membrane 19 against plasma etching whilst not increasing EUV transmission loss in the imaging area. The protective portion 28 is not required in the imaging area since the high-power EUV beam heats the membrane 19 to a high enough temperature to ensure that no, or only negligible, (CNT) etching takes place in the imaging area. Outside the imaging area, where the membrane is relatively cold in comparison to the imaging area, the EUV transmission values are irrelevant, or at least less important than in the imaging area. By protecting from plasma, the partial coating (protective portion 28 on the second portion 38) on the membrane 19 enables a longer lifetime of the parts of the (CNT) membrane 19 which are not heated during lithographic operation, and thus a longer lifetime of the membrane 19 as a whole.

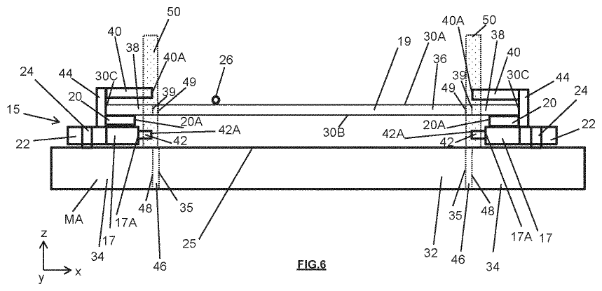

FIG. 6 schematically depicts a cross-sectional view of the pellicle 15 and the patterning device MA according to another embodiment. For clarity, the same reference numerals will be used for the same and corresponding parts as were depicted in FIG. 2 and for brevity these parts will not be discussed further in detail.

The pellicle 15 of FIG. 6 differs over the pellicle in FIG. 2 at least in that the protective portion comprises a plurality of shields, a front shield 40 and a back shield 42. Furthermore, the pellicle frame 17 comprises shield attachment member or members 44 (e.g. a protrusion or stud) which are attached or attachable to the front shield 40 at the peripheral edge of the front shield 40. The shield attachment members 44 may be on the X edges of the pellicle 15. The shield attachment members 44 may be coincident or offset (as shown in FIG. 6) from the attachment members 24. It will be appreciated that the precise arrangement depicted is just an example and other suitable arrangements to support the front shield may be used. Thus, more generally, the pellicle frame 17 supports the front shield 40 on the first side 30A (i.e. front side) of the membrane 19. In other embodiments, the shield may be supported by another different component.

In addition, the pellicle frame 17 supports the back shield 42 on an opposite second side 30B (i.e. back side) of the membrane 19. In this embodiment, the back shield 42 is attached or attachable to the pellicle frame 17 on an inward edge 17A of the pellicle frame 17. In other embodiments, the back shield 42 may be supported by the shield attachment member 44 in a similar way to the front shield 40. For example, the back shield 42 may be located between the border 20 and the pellicle frame 17 with the peripheral edge of the back shield 42 being attached or attachable to the shield attachment member 44.

The front shield 40 is supported such that there is a front gap between the first side 30A (i.e. front side) of the membrane 19 and the front shield 40. In embodiments, the front gap may be less than 1000 μm. In other embodiments, the front gap may be less than 2000 μm. In general, the front gap may be a distance such that plasma flux is sufficiently suppressed. Having a front gap allows sagging room for the membrane 19 and the size of the front gap may be chosen to maximize sagging room for the membrane whilst keeping within the allowed volume available in front of the membrane 19. Also, the thickness of the front shield 40 may be chosen to be something that is easily commercially available (such as 200 μm) but may also be chosen to be less (or more) than 200 μm, e.g. if a different size of the front gap is desired. It will be appreciated that, in some embodiments

Similarly, the back shield 42 is supported such that there is a back gap between the second side 30B (i.e. back side) of the membrane 19 and the back shield 42. In embodiments, the back gap may be less than 1000 μm. The back gap may be less than 2000 μm. In general, the back gap may be a distance such that plasma flux is sufficiently suppressed. In embodiments where the border 20 is between the back shield 42 and the membrane 19, the size of the back gap may be dictated by the thickness of the border 20. Otherwise, the back gap may be a similar size to the front gap. The most critical dimension may be the front gap since there may be little or no tolerances here to allow a shield to be positioned. Thus, thinner shields (<1000 μm) may be preferable. There may be enough space between the membrane and the X direction reticle masking blades, the Y nozzle and/or the EUV inner pod to fit the front shield 40.

It will be appreciated that, in some embodiments, there may be substantially no, or at least, very little, front gap between the first side 30A (i.e. front side) of the membrane 19 and the front shield 40. Similarly, in some embodiments, there may be substantially no, or at least, very little, back gap between the second side 30B (i.e. back side) of the membrane 19 and the back shield 42. Thus, in some embodiments, the front shield 40 and/or the back shield 42 may be directly on, in contact with and/or supported by the membrane 19. In other words, the front gap and/or back gap may be optional. For the back shield 42, this may be the case in embodiments where there is no border 20 and the membrane 19 is directly on the pellicle frame 17.

Although there are respective front and back gaps between the respective front and back shields 40, 42, and the membrane 19, it will be appreciated that the front and back shields may still be considered to be on the front and back sides of the membrane. In other words, a protective portion “on at least one side of the membrane” does not necessarily need to mean that the protective portion (e.g. shields) is directly on or in contact with or supported by the membrane. Thus, this may also cover, for example, the protective portion (e.g. a shield) being on a side of the membrane a distance (a gap) away from the membrane and the protective portion may be supported by another component (such as a pellicle frame). Similarly, the protective portion “on a first side and an opposite second side of the membrane” may also cover, for example, the protective portion (e.g. a first shield) being on a first side (e.g. front side) of the membrane a distance (e.g. a front gap) away from the membrane and also (e.g. a second shield) being on an opposite second side (e.g. back side) of the membrane a distance (e.g. a back gap) away from the membrane, with (e.g. the first and second shields) being supported by another component (such as the pellicle frame).

Both the front shield 40 and the back shield 42 extend inwardly (parallel to the x-axis) towards the centre of the membrane 19 with respect to the inward edge 17A of the pellicle frame 17. In embodiments, the front shield 40 and the back shield 42 may extend at least 1500 μm (e.g. in the X direction) inwardly with respect to the inward edge 17A of the pellicle frame 17. In some embodiments, the front shield 40 and the back shield 42 may, additionally or alternatively, extend inwardly (e.g. at least 1500 μm, e.g. in the X direction) towards the centre of the membrane 19 with respect to an inward edge 20A of the border 20. For the former option, this may be when the inward edge 17A of the pellicle frame 17 and the inward edge 20A of the border 20 correspond (line up) with each other. In the embodiment of FIG. 6, the front shield 40 and the back shield 42 extend inwardly to the same extent (i.e. to the same distance as each other from the pellicle frame 17 (and the same distance as each other from the border 20, albeit that there are different distances to the pellicle frame 17 and to the border 20 as their inward edges 17A, 20A do not line up with each other)). However, it will be appreciated that, in other embodiments, the front shield 40 and the back shield 42 may extend different distances from the pellicle frame 17 and/or the border 20. Furthermore, the front shield 40 and the back shield 42 may extend different distances in the X direction (for the X borders) and in the Y direction (for the Y borders).

In the embodiment of FIG. 2, the first portion 36 and the second portion 38 of the membrane 19 corresponded to the predetermined exposure region 32 and the non-exposure region 34 of the patterning device MA respectively. However, in the embodiment of FIG. 6, the first portion 36 corresponds to an extended region 46 of the patterning device MA that is greater than the exposure region 32 of the patterning device MA. The dotted lines 35 still delimit the exposure region 32 and the non-exposure region 34 of the patterning device MA with the extended region 46 of the patterning device MA being shown delimited by the dotted lines 48. It will be understood that the extended region 46 of the patterning device MA includes the exposure region 32 of the patterning device MA and the portion between the dotted lines 35 and 48. The exposure region 32 of the patterning device MA may be referred to as a quality area. Other definitions of quality area may be used, such as a region where optical properties are measured, an area for inspection performance, and an area for clamp performance.

Although the first portion 36 and the second portion 38 of the membrane 19 are still delimited as shown by dotted lines 39, the dotted lines 39 in FIG. 6 correspond (line up along the z-axis) with the dotted lines 48 delimiting the extended region 46 of the patterning device MA, rather than the dotted lines 35 delimiting the exposure region 32 and the non-exposure region 34 of the patterning device MA. Instead, the portion of the membrane 19 which may be considered to be an exposed region (as it is the only potion that will receive EUV radiation during imaging) and the portion of the membrane 19 which may be considered to be an unexposed region (as it doesn't receive EUV radiation during imaging) are delimited by dotted lines 49. It will be understood that the inward extent of the front shield 40 (i.e. inward edge 40A) and the back shield 42 (i.e. inward edge 42A) corresponds (lines up along the z-axis) with the dotted lines 39 delimiting the first portion 36 and the second portion 38 of the membrane 19, and corresponds (lines up) with the dotted lines 48 of the extended region 46 of the patterning device MA. It will be appreciated that, in some embodiments, the first portion 36 and the second portion 38 of the membrane 19 may be the same as in FIG. 2 (i.e. that the front shield and/or back shield extend inwardly all the way to correspond to the exposure region 32 of the pattering device MA). It is important that the shields do not extend such that they will encroach into the EUV radiation beam path over the imaging area as (e.g. unless it is as thin as a pellicle) they would then be printed on the wafer, which is not desired.

In embodiments, the extended region 46 of the patterning device MA extends to a predetermined distance outwardly from the exposure region 32 of the patterning device MA. For example, the extended region 46 may extend to 1000 μm outwardly from the exposure region 32. This may be so the shields 40, 42, do not interfere with the EUV radiation (the EUV light cone).

In embodiments, the second portion 38 of the membrane 19 extends to a predetermined distance inwardly (parallel to the x-axis) with respect to the inward edge 17A of the pellicle frame 17 (and to a predetermined distance inwardly (parallel to the x-axis) with respect to the inward edge 20A of the border 20). In embodiments where the inward edge 17A of the pellicle frame 17 and the inward edge 20A of the border 20 correspond (line up) with each other, the predetermined distances may be the same. In embodiments, the second portion 38 of the membrane 19 may extend at least 1500 μm inwardly with respect to the inward edge 17A of the pellicle frame 17. In embodiments, the second portion 38 of the membrane 19 may extend at least 1500 μm inwardly with respect to the inward edge 20A of the border 20).

The outward extent of the extended region 46 of the patterning device MA (i.e. shown by the dotted lines 48) is within a blackborder of the patterning device MA. The shields 40, 42 extend past (inwardly) the border 20 (and the frame 17) of the pellicle 15 but remain outside the quality area (the exposure region 32) of the patterning device MA. Since the shields 40, 42 extend inwardly with respect to the border 20 (and the frame 17) of the pellicle 15, they have an advantage of protecting the pellicle from plasma (i.e. hydrogen plasma etching damage).

Membranes (e.g. CNT membranes) may be protected from hydrogen plasma etching damage in the lithographic apparatus LA through the use of a (periodic) heater pulse. The heat 50 from the pellicle heater (not shown) is illustrated in FIG. 6 and is shown to be incident on a region of the membrane substantially outward to the exposed region of the membrane 19 (i.e. external to the dotted lines 49). It is important to heat up the region outward from the exposed region of the membrane 19 as it will not be heated by the EUV radiation during imaging and thus will be more susceptible to hydrogen etching (as explained above). It will be appreciated that the region that the heat 50 covers may be different from that shown in FIG. 6, e.g. it may extend all the way to the border 20 or pellicle frame 17, or even further to cover some or all of the border 20 and pellicle frame 17. It may be found that irradiating the border 20 is not worthwhile due to its high thermal mass.

However, the pellicle heater only heats up the thin membrane 19. The border 20 of the pellicle 15 would stay relatively cold, since it is a much thicker body with a higher heat-capacity and heat-conductivity. Thus, it has been realized that there would be an area of membrane 19 of finite size, close to the border 20, which could not be sufficiently heated by a heating device (e.g. to the extent required to mitigate hydrogen etching to a satisfactory level), since it is connected to the relatively cold border 20. It will be appreciated that this is also applicable in embodiments where there is no border, i.e. where the membrane 19 is formed directly on the frame 17. That is, the frame 17 of the pellicle 15 would stay relatively cold, due to thermal mass, and there would be an area of membrane 19 of finite size, close to the frame 17, which could not be sufficiently heated by a heating device (e.g. to the extent required to mitigate hydrogen etching to a satisfactory level), since it is connected to the relatively cold frame 17.

This area of the membrane 19 close to the border 20 is a problem, since the margin between exposed region of the membrane 19 and border 20 is only a few mm in size in the +/−X directions (+/−Y direction may be a bit more forgiving e.g. because the distance between the exposed region of the membrane 19 and the border 20 may be greater in the Y direction than the X direction and thus the cold part of the membrane 19 (close to the border 20) may be further away from the plasma and so will be less susceptible to etching as it receives less plasma). This narrow distance means a non-negligible plasma dose will be received by membrane 19 on or close to the border 20, and may cause membrane 19 failure through etching damage.

It may be shown that the region of highest etching on a CNT membrane is not in the field but rather outside the exposure area, i.e. under the reticle masking blades. The reticle masking blades do not provide the shielding function (in either the X or Y direction) as they are too far away from the membrane and there is significant plasma flux leak under the reticle masking blades (in both X and Y directions).

The shields 40, 42, protect the pellicle from etching damage by suppressing plasma flux to the area of the membrane 19 close to the border 20. That is, the relatively small gap (front gap and back gap) between the shields 40, 42, and the membrane 19 prevents some of the plasma flux from reaching the problem area. The closer the shields 40, 42 are located to the membrane 19, the more effective they are to stop plasma diffusing under them. Furthermore, the shields 40, 42 are transparent to the wavelength of the radiation (e.g. IR radiation and/or DUV radiation) from the pellicle heater, and so this allows the membrane 19 in between the shields 40, 42 to heat up. The shields 40, 42, may comprise aluminium oxide (Al₂O₃), sapphire, aluminium oxide (Al₂O₃) coated glass, or sapphire coated glass. The front gap and the back gap being less than 1000 μm may be sufficient to suppress plasma flux to a desirable level. In addition, the shields 40, 42, are inert in plasma. The shields 40,42, are irradiated by intense plasma, which may cause erosion of the shield (bad for its function), and the erosion products may deposit on the mask (reticle) or other part of the lithographic apparatus LA (bad for the lithographic apparatus LA function). Therefore, all parts in the lithographic apparatus LA (including the shields), especially close to light (EUV radiation) beam, should have non-outgassing requirements.

The etch damage of a CNT pellicle after exposure may be shown and there may be a ring around the exposure area (which may be referred to as a “ring of fire”) which is most heavily affected (i.e. has most etch damage). This “ring of fire” may coincide with the blackborder of the reticle, making it harder to image in the lithographic apparatus LA. The “ring of fire” is between the exposed region of the membrane 19 and the border 20 (and the frame 17) along the x-axis. Thus, the shields 40, 42 should be positioned to cover the “ring of fire” or the expected location of the “ring of fire”. For example, the second portion 38 of the membrane 19, and thus the shields 40, 42, may extend at least 1500 μm (e.g. in the X direction) inwardly with respect to the inward edge 17A of the pellicle frame 17 (and/or the inward edge 20A of the border 20) so that the “ring of fire” location is covered. As examples, the “ring of fire” may be located 1000-2000 μm in the X direction and/or 1000-4000 μm in the Y direction away from the exposure region 32 of the patterning device MA (i.e. away from the defined image field). Thus, the second portion 38 of the membrane 19, and thus the shields 40, 42, may extend at least to cover these exemplary locations of the “ring of fire”. For example, the first portion 36 of the membrane 19 may correspond to the extended region 46 which extends 1000 μm outwardly from the predetermined exposure region 32 of the patterning device MA. The extended region 46 may extend outwardly from the predetermined exposure region 32 of the patterning device MA at least one of in a range of 1000 μm-2000 μm (e.g. in the X direction) and in a range of 1000-4000 μm (e.g. in the Y direction). For example, if the “ring of fire” was located 1800 μm from the predetermined exposure region 32 of the patterning device MA in the X direction, the first portion 36 of the membrane 19 may extend 1700 μm from the predetermined exposure region 32 so as the “ring of fire” would be covered by the front and/or back shields 40, 42 (since the second portion 38 of the membrane 19 would extend a corresponding distance). Examples include that the second portion 38 (and thus the front and/or back shields 40,42) extends inwardly with respect to the inward edge of the pellicle frame and/or the border at least 1300 μm, at least 1500 μm, at least 2300 μm, or in a range of 1300 μm-2300 μm (e.g. with respect to the X direction).

FIG. 6 shows shields 40, 42 along the X-edges (i.e. they extend into the page in the Y direction and shield the X-borders) but it will be understood that these shields also extend along the Y-edges (i.e. they shield the Y-borders). That is, these shields may be considered to be continuous such that there may be considered to be a single front shield and a single back shield. For full field exposures, where the entire quality area available is used, the shields 40, 42 may prevent the appearance of a “ring of fire” in both X- and Y-edges. In some embodiments, there may be shields along only the X-edges and/or the Y-edges. The front shields or back shields may be not continuous and may be separated (e.g. in the situation where there are only shields along the X-edges). Furthermore, in some embodiments, there may be shields along both the X- and Y-edges but they may be separated (i.e. not continuous), e.g. in the corners. In any case, it may be preferable for there to be a shield (e.g. front shield and/or back shield) on all 4 edges (i.e. both X-edges and Y-edges) of the membrane 19.

Using the shields 40, 42 may increase the lifetime of a pellicle (e.g. a CNT pellicle) in a lithographic apparatus LA due to an, at least, reduction of plasma etch effects. Using the shields 40, 42 may be advantageous over coating on border and membrane edges since coating may not be stable to thermal stresses and they may require careful alignment of deposition to the exposure field. Furthermore, coatings may only work to protect the border. In addition, using the shields 40, 42 may be advantageous over a thicker CNT layer outside the exposure region of the reticle as this may require challenging process control to align thicker border layer on top of thin membrane. Furthermore, the thicker membrane close to the border may still be etched away, which means a shorter lifetime than with shields, and more carbon etch products in the lithographic apparatus LA.

It will be appreciated that, although two shields are shown in FIG. 6, in some embodiments, there may be a single shield (i.e. a front shield or a back shield) as this would give at least some protection and/or maybe sufficient to prevent etching by the required extent. If there is a single shield, it may be preferable that it is a front shield, as a front shield would provide more protection than a back shield.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims and clauses set out below.
1. A pellicle for use in a lithographic apparatus, the pellicle comprising:
a membrane, the membrane comprising a first portion and a second portion; and
a protective portion at the second portion on at least one side of the membrane.
2. The pellicle of clause 1, wherein the second portion, in use, does not receive EUV imaging radiation or receives only a fraction of the EUV imaging radiation received by the first portion.
3. The pellicle of either of clauses 1 or 2, wherein the first portion substantially corresponds to a predetermined exposure region of a patterning device for use with the pellicle.
4. The pellicle of clause 3, wherein the first portion is substantially the same size as the predetermined exposure region of the patterning device.
5. The pellicle of any preceding clause, wherein the second portion is at a periphery of the membrane.
6. The pellicle of clause 5, wherein the pellicle comprises a border at the periphery of the membrane, wherein the second portion coincides with the border.
7. The pellicle of any preceding clause, wherein the protective portion comprises a material that is suitable to protect the second portion of the membrane from hydrogen etching.
8. The pellicle of any preceding clause, wherein the protective portion is on at least one of:
a first side and an opposite second side of the membrane; and
an edge of the membrane.
9. The pellicle of any preceding clause, wherein the protective portion comprises a capping material covering the second portion.
10. The pellicle of clause 9, wherein the capping material comprises at least one of: carbon nanotubes, graphene, amorphous carbon, (low melting point metals), molybdenum (Mo), yttrium (Y), yttrium oxide (YₐO_{b}), aluminium oxide (Al₂O₃) (AlO₂), hafnium oxide (HfO₂), zirconium oxide (ZrO₂), ruthenium (Ru), platinum (Pt), gold (Au), zirconium nitride (ZrN), aluminium (Al) zirconium (Zr), silicon (Si), silicon carbide (SiC) silicon oxide (SiOₐ), boron (B), boron carbide (B₄C), boron nitride (BN), titanium (Ti), and titanium nitride (TiN).
11. The pellicle of any of clauses 1-8, wherein the membrane comprises the protective portion and the protective portion comprises the same material as the first and second portions.
12. The pellicle of any of clauses 1-8, wherein the pellicle comprises a pellicle frame and the protective portion comprises a shield, wherein the shield is supported by the pellicle frame.
13. The pellicle of clause 12, wherein the shield is separated from the membrane by a gap, preferably wherein the gap is less than 1000 μm or less than 2000 μm.
14. The pellicle of either of clauses 12 or 13, wherein the shield is at least one of: substantially transparent to heater radiation, substantially transparent to IR radiation, substantially transparent to DUV radiation, and inert in plasma.
15. The pellicle of clause 14, wherein the shield comprises at least one of: aluminium oxide (Al₂O₃), sapphire, aluminium oxide (Al₂O₃) coated glass, and sapphire coated glass.
16. The pellicle of any of clauses 12-15, wherein the protective portion comprises a plurality of shields, a first shield on a first side of the membrane and a second shield on an opposite second side of the membrane.
17. The pellicle of any of clauses 1-2 and clauses 5-16 when not dependent on clauses 3 and 4, wherein the first portion substantially corresponds to an extended region greater than the predetermined exposure region of a patterning device for use with the pellicle.
18. The pellicle of clause 17, wherein the extended region extends to a predetermined distance outwardly from the predetermined exposure region of the patterning device.
19. The pellicle of clause 18, wherein the extended region extends outwardly from the predetermined exposure region of the patterning device at least one of 1000 μm, in a range of 1000-2000 μm and in a range of 1000-4000 μm.
20. The pellicle of any preceding clause, wherein the second portion extends to a predetermined distance inwardly with respect to an inward edge of a pellicle frame and/or a border at the periphery of the membrane.
21. The pellicle of clause 20, wherein the second portion extends inwardly with respect to the inward edge of the pellicle frame and/or the border at least one of: at least 1300 μm, at least 1500 μm, at least 2300 μm, in a range of 1300 μm-2300 μm.
22. The pellicle of any preceding clause, wherein the membrane comprises carbon nanotubes.
23. A lithographic apparatus operable to form an image of a patterning device on a substrate using a radiation beam, the lithographic apparatus comprising a pellicle disposed in a path of the radiation beam, the pellicle according to any of the preceding clauses.
24. A method for forming a pellicle for use in a lithographic apparatus, the method comprising:
providing a membrane comprising a first portion and a second portion,
providing a protective portion at the second portion on at least one side of the membrane.
25. The method of clause 24, further comprising providing the protective portion using an additive method or a subtractive method.
26. The method of clause 25, further comprising:
providing the protective portion using an additive method, wherein the protective portion comprises a capping material;
depositing the capping material over the second portion to cover the second portion.
27. The method of clause 26, further comprising masking the first portion using a masking element.
28. The method of clause 27, wherein the masking element substantially corresponds to a predetermined exposure region of a patterning device for use with the pellicle.
29. The method of any of clauses 26-28, further comprising depositing the capping material using at least one of: thermal evaporation, e-beam evaporation, e-beam deposition, pulsed laser deposition, atomic layer deposition and remote plasma sputtering.
30. The method of clause 25, further comprising:
providing the protective portion using a subtractive method, wherein the protective portion comprises a capping material;
applying the capping material over the first portion and the second portion, and
removing the capping material from the first portion.
31. The method of clause 30, the method further comprising removing the capping material from the first portion using at least one of: laser annealing, laser ablating, reactive ion etching, and lift-off.
32. The method of either of clauses 30 or 31, wherein the capping material is a volatile or thermally unstable material for being desorbed by EUV radiation.
33. The method of clause 25, further comprising providing the protective portion using a subtractive method including providing the membrane with a thickness, and partially removing the first portion to reduce the thickness of the first portion, wherein the membrane comprises the protective portion and the protective portion comprises the same material as the first and second portions.
34. The method of clause 33, further comprising etching the first portion in hydrogen plasma.
35. The method of clause any of clauses 24-34, further comprising providing the protective portion on at least one of: a first side and an opposite second side of the membrane; and an edge of the membrane.
36. The method of any of clauses 24-35, further comprising providing the first portion to substantially correspond to a predetermined exposure region of a patterning device for use with the pellicle.
37. The method of any of clauses 24-36, further comprising providing the protective portion during at least one of fabrication of the pellicle, fabrication of a patterning device and fabrication of a substrate.
38. The method of clause 24, further comprising providing a pellicle frame, wherein the protective portion comprises a shield and the pellicle frame supports the shield.
39. The method of clause 38, further comprising separating the shield from the membrane by a gap.
40. The method of either of clauses 38 or 39, further comprising providing a plurality of shields, a first shield on a first side of the membrane and a second shield on an opposite second side of the membrane.
41. The method of any of clauses 38-40, further comprising providing the first portion to substantially correspond to an extended region greater than the predetermined exposure region of a patterning device for use with the pellicle.
42. A pellicle for use in a lithographic apparatus, the pellicle comprising:
a membrane, the membrane comprising a first portion and a second portion; and
a protective portion at the second portion on at least one side of the membrane.
43. The pellicle of clause 42, wherein the second portion, in use, does not receive EUV imaging radiation or receives only a fraction of the EUV imaging radiation received by the first portion.
44. The pellicle of either of clauses 42 or 43, wherein the first portion substantially corresponds to a predetermined exposure region of a patterning device for use with the pellicle.
45. The pellicle of clause 44, wherein the first portion is substantially the same size as the predetermined exposure region of the patterning device.
46. The pellicle of any preceding clause, wherein the second portion is at a periphery of the membrane.
47. The pellicle of clause 46, wherein the pellicle comprises a border at the periphery of the membrane, wherein the second portion coincides with the border.
48. The pellicle of any preceding clause, wherein the protective portion comprises a material that is suitable to protect the second portion of the membrane from hydrogen etching.
49. The pellicle of any preceding clause, wherein the protective portion is on at least one of: a first side and an opposite second side of the membrane; and an edge of the membrane.
50. The pellicle of any preceding clause, wherein the protective portion comprises a capping material covering the second portion.
51. The pellicle of clause 50, wherein the capping material comprises at least one of: carbon nanotubes, graphene, amorphous carbon, (low melting point metals), molybdenum (Mo), yttrium (Y), yttrium oxide (YₐO_{b}), aluminium oxide (Al₂O₃) (AlO₂), hafnium oxide (HfO₂), zirconium oxide (ZrO₂), ruthenium (Ru), platinum (Pt), gold (Au), zirconium nitride (ZrN), aluminium (Al) zirconium (Zr), silicon (Si), silicon carbide (SiC) silicon oxide (SiOₐ), boron (B), boron carbide (B₄C), boron nitride (BN), titanium (Ti), and titanium nitride (TiN).
52. The pellicle of any of clauses 42-49, wherein the membrane comprises the protective portion and the protective portion comprises the same material as the first and second portions.
53. The pellicle of any preceding clause, wherein the membrane comprises carbon nanotubes.
54. A lithographic apparatus operable to form an image of a patterning device on a substrate using a radiation beam, the lithographic apparatus comprising a pellicle disposed in a path of the radiation beam, the pellicle according to any of the preceding clauses.
55. A method for forming a pellicle for use in a lithographic apparatus, the method comprising:
providing a membrane comprising a first portion and a second portion,
providing a protective portion at the second portion on at least one side of the membrane.
56. The method of clause 55, further comprising providing the protective portion using an additive method or a subtractive method.
57. The method of clause 56, further comprising:
providing the protective portion using an additive method, wherein the protective portion comprises a capping material;
depositing the capping material over the second portion to cover the second portion.
58. The method of clause 57, further comprising masking the first portion using a masking element.
59. The method of clause 58, wherein the masking element substantially corresponds to a predetermined exposure region of a patterning device for use with the pellicle.
60. The method of any of clauses 57-59, further comprising depositing the capping material using at least one of: thermal evaporation, e-beam evaporation, e-beam deposition, pulsed laser deposition, atomic layer deposition and remote plasma sputtering.
61. The method of clause 56, further comprising:
providing the protective portion using a subtractive method, wherein the protective portion comprises a capping material;
applying the capping material over the first portion and the second portion, and
removing the capping material from the first portion.
62. The method of clause 61, the method further comprising removing the capping material from the first portion using at least one of: laser annealing, laser ablating, reactive ion etching, and lift-off.
63. The method of either of clauses 61 or 62, wherein the capping material is a volatile or thermally unstable material for being desorbed by EUV radiation.
64. The method of clause 56, further comprising providing the protective portion using a subtractive method including providing the membrane with a thickness, and partially removing the first portion to reduce the thickness of the first portion, wherein the membrane comprises the protective portion and the protective portion comprises the same material as the first and second portions.
65. The method of clause 64, further comprising etching the first portion in hydrogen plasma.
66. The method of clause any of clauses 55-65, further comprising providing the protective portion on at least one of:
a first side and an opposite second side of the membrane; and
an edge of the membrane.
67. The method of any of clauses 55-66, further comprising providing the first portion to substantially correspond to a predetermined exposure region of a patterning device for use with the pellicle.
68. The method of any of clauses 55-67, further comprising providing the protective portion during at least one of fabrication of the pellicle, fabrication of a patterning device and fabrication of a substrate.

1. A pellicle for use in a lithographic apparatus, the pellicle comprising:
a membrane comprising carbon nanotubes, the membrane comprising a first portion and a second portion; and
a protective portion at the second portion on at least one side of the membrane, wherein the protective portion comprises a material that is suitable to protect the second portion of the membrane from etching.

2. The pellicle of claim 1, wherein the second portion, in use, does not receive EUV imaging radiation or receives only a fraction of the EUV imaging radiation received by the first portion.

3. The pellicle of claim 1, wherein the first portion substantially corresponds to a predetermined exposure region of a patterning device for use with the pellicle.

4. The pellicle of claim 3, wherein the first portion is substantially the same size as the predetermined exposure region of the patterning device.

5. The pellicle of claim 1, wherein the second portion is at a periphery of the membrane.

6. The pellicle of claim 5, wherein the pellicle comprises a border at the periphery of the membrane, wherein the second portion coincides in size with the border, and the border is provided on an opposite side of the membrane than the protective portion.

7. The pellicle of claim 1, wherein the protective portion comprises a material that is suitable to protect the second portion of the membrane from hydrogen etching.

8. The pellicle of claim 1, wherein the protective portion is on a first side and an opposite second side of the membrane; and/or on an edge of the membrane.

9. The pellicle of claim 1, wherein the protective portion comprises a capping material covering the second portion.

10. The pellicle of claim 9, wherein the capping material comprises at least one selected from: carbon nanotubes, graphene, amorphous carbon, (low melting point metals), molybdenum (Mo), yttrium (Y), yttrium oxide (YₐO_{b}), aluminium oxide (Al₂O₃) (AlO₂), hafnium oxide (HfO₂), zirconium oxide (ZrO₂), ruthenium (Ru), platinum (Pt), gold (Au), zirconium nitride (ZrN), aluminium (Al), zirconium (Zr), silicon (Si), silicon carbide (SiC), silicon oxide (SiOₐ), boron (B), boron carbide (B₄C), boron nitride (BN), titanium (Ti), or titanium nitride (TiN).

11. The pellicle of claim 1, wherein the membrane comprises the protective portion and the protective portion comprises the same material as the first and second portions.

12. The pellicle of claim 1, wherein the membrane comprises a layer having the same type of carbon nanotubes in both the first portion and the second portion, and wherein the material of the protective portion covering the second portion of the membrane is transparent to at least a fraction of the EUV imaging radiation received by the first portion.

13. A lithographic apparatus operable to form an image of a patterning device on a substrate using a radiation beam, the lithographic apparatus comprising a pellicle disposed in a path of the radiation beam, the pellicle according to claim 1.

14. A method for forming a pellicle for use in a lithographic apparatus, the method comprising:
providing a membrane comprising carbon nanotubes, the membrane comprising a first portion and a second portion,
providing a protective portion at the second portion on at least one side of the membrane, wherein the protective portion comprises a material that is suitable to protect the second portion of the membrane from etching.

15. The method of claim 14, further comprising providing the protective portion using an additive method or a subtractive method.

16.-27. (canceled)

28. The pellicle of claim 1, wherein the pellicle comprises a pellicle frame and protective portion comprises a shield, wherein the shield is supported by a pellicle frame.

29. The pellicle of claim 28, wherein the shield is separated from the membrane by a gap.

30. The pellicle of claim of 1, wherein the protective portion comprises a plurality of shields, a first shield on a first side of the membrane and a second shield on an opposite second side of the membrane.

31. The pellicle of claim 1, wherein the first portion substantially corresponds to an extended region greater than the predetermined exposure region of a patterning device for use with the pellicle.

32. The pellicle of claim 1, wherein the second portion extends to a predetermined distance inwardly with respect to an inward edge of a pellicle frame and/or a border at the periphery of the membrane.
